(19) United States
(12) Patent Application Publication
(10) Pub. No.: US 2015/0342049 A1
(43) Pub. Date: Nov. 26, 2015

(54) MULTI-PIECE WIRING BOARD AND METHOD FOR PRODUCING THE SAME

(71) Applicant: KYOCERA CIRCUIT SOLUTIONS, INC., Kyoto (JP)

(72) Inventors: Tomoharu TSUCHIDA, Yasu-shi (JP); Kazuki OKA, Kusatsu-shi (JP); Daichi OHMAE, Kusatsu-shi (JP)

(73) Assignee: KYOCERA CIRCUIT SOLUTIONS, INC., Kyoto (JP)

(21) Appl. No.: 14/718,368

(22) Filed: May 21, 2015

(30) Foreign Application Priority Data
May 22, 2014 (JP) 2014-105770

(51) Int. Cl. H05K 1/14; H05K 3/36; H01L 21/78; H05K 3/10

(52) U.S. Cl. CPC H05K 1/142; H05K 3/10; H05K 3/36; H01L 21/78; H05K 2201/09036

(57) ABSTRACT

The multi-piece, wiring board according to the embodiment of the present invention includes a supporting board including a frame portion formed on an upper surface of a bottom plate, the frame portion configured to divide the upper surface of the bottom plate into a plurality of product forming regions, and a wiring board formed on the upper surface of the bottom plate in. each of the product forming regions, the: wiring board including an insulating layer formed so as to expose an upper surface of the frame portion, and a wiring conductor formed on the insulating layer.

### BACKGROUND OF THE INVENTION

1. Technical Field

The present invention relates to a multi-piece wiring, board including a plurality of small wiring boards arranged and formed on one supporting board, and a producing method thereof,

2. Background

Conventionally, as a multi-piece wiring board for CSP (Chip Size Package)a multi-piece wiring board including a plurality of small wiring boards which contain an insulating layer and a metal layer laminated on the supporting board made of metal, formed integrally by being arranged in vertical and horizontal directions is known. The CSP is described, for example, in Japanese Unexamined Patent Application No. 2004-111641.

In such a multi-piece wiring board, a semiconductor element is mounted on each of the small wiring boards formed integrally on the supporting board, and a sealing resin layer is formed so as to cover the semiconductor element on substantially the entire surface of the upper surface. Next, after the supporting board is removed by etching, cutting and dividing are performed by dicing along the boundary of each of the small wiring boards. In this way, a plurality of small semiconductor devices where semiconductor elements mounted on the wiring boards are sealed by a sealing resin are simultaneously and intensively produced.

However; in the conventional multi-piece wiring board described above, the resin layer forming the wiring board is thin, and the mechanical strength is low. Therefore, when the dicing is performed after the supporting board is removed by etching, the cracking or chipping is likely to occur in the wiring board by the stress applied during the dicing. In addition, the multi-piece wiring board and the sealing resin thereon are divided into small semiconductor devices by dicing, and therefore, the shape of the divided wiring board is limited to the quadrangular shape having sharp corners. Therefore, when a wiring board having a quadrangular shape with rounded corners or a shape other than a quadrangle is requested depending on the design of the housing of the electronic apparatus where a semiconductor device in which a semiconductor element is mounted on the wiring board is housed, it is difficult to meet the request.

### SUMMARY

The present invention has an object to provide a multi-piece wiring board where the cracking or chipping is less likely to occur in a wiring board during the dicing. Furthermore, the present invention has an object to provide a multi-piece wiring board capable of forming a wiring board having a quadrangular shape with rounded corners or another shape other than a quadrangle after the dividing by dicing.

The multi-piece wiring board according to the first embodiment of the present invention includes: a supporting board including a frame portion formed on an upper surface of a bottom plate, the frame portion configured to divide the upper surface of the bottom plate into a plurality of product forming regions, and a wiring board formed on the upper surface of the bottom plate in each of the product forming regions, the wiring board including an insulating layer formed so as to expose an upper surface ox the frame portion, and a wiring conductor formed on the insulating layer.

In addition, a method for producing a multi-piece wiring board according to the first embodiment of the present invention includes the steps of: forming an insulating layer covering at least each of product forming regions on an upper surface of a bottom, plate having a plurality of the product forming regions on the upper surface, forming a wiring conductor on the insulating layer of each of the product forming regions; exposing the upper surface of the bottom plate by removing the insulating layer formed in a region other than each of the product forming regions; and forming a frame portion configured to divide the upper surface of the bottom plate into each of the product forming regions on the bottora plate by depositing a plated conductor layer on the upper surface of the exposed bottom plate.

According to the multi-piece wiring board according to the first embodiment of the present invention, the multi-piece wiring board has the configuration described above, and therefore, when a semiconductor element is mounted on each of the wiring boards, and a sealing resin layer covering the semiconductor element is formed over substantially the entire surface of the upper surface, subsequently the supporting board is removed by etching, then the boundary of each of the wiring boards is formed by the step where the frame portion is removed, and the wiring board itself is not present. Therefore, when the cutting and dividing are performed by dicing along the boundary of each of the wiring boards, it is sufficient to cut only the sealing resin layer, and the cracking or chipping does not occur in the wiring board.

Furthermore, according to the multi-piece wiring board according to the first embodiment of the present invention, the product forming regions are divided by the frame portion so that the product forming regions include the openings containing, for example, a quadrangular shape with rounded corners or a shape different from a quadrangle, and the wiring board having the external shape corresponding to the shape of the opening is formed. Thus, a semiconductor element is mounted on each of the wiring boards, and a sealing resin layer configured to cover the semiconductor element over substantially the entire surface of the upper surface is formed, subsequently the supporting board is removed by etching, then only the sealing resin layer is cut by dicing along the boundary of each of the wiring boards, whereby, although the sealing resin has a quadrangular shape with sharp corners, the wiring board itself can have a quadrangular shape with rounded corners or a shape other than a quadrangle.

In addition, according to the method for producing a multi-piece wiring board according to the first embodiment of the present invention, it is possible to provide a multi-piece wiring board where the cracking or chipping is less likely to occur in the -wiring board during the dicing by the above processes. Furthermore, in case of removing the insulating layer around the product forming region, when the insulating layer is removed so that the shape of the wiring board formed on the bottom plate includes a quadrangle with rounded corners or a shape other than a quadrangle, after the dividing by dicing, it is possible to provide a multi-piece wiring board capable of forming a wiring board having a quadrangle with rounded corners or another shape other than a quadrangle.

A multi-piece wiring board according to the second embodiment of the present invention includes: a supporting board including metal foil laminated on an upper surface of a bottom plate in a state where at least a central portion of the metal foil is peelable from the bottom plate; a frame portion including a plated metal layer, the frame portion configured to divide a central portion of an upper surface of the metal foil into a plurality of product forming regions in the central portion of the upper surface of the metal foil, the frame portion formed on the metal foil; and a wiring board formed in each of the product forming regions, the wiring board inclulding an insulating layer formed so as to foe in close contact with an inner wall of the product forming region, and a wiring conductor formed on the insulating layer.

In addition, the method for producing a multi-piece wiring board according to the second embodiment of the present invention includes the steps of: laminating metal foil including a plurality of product forming regions in a central portion of an upper surface of the metal foil on an upper surface of a bottom plate in a state where at least the central portion is peelable from the bottom plate; forming an insulating layer on the entire surface of at least the central portion on the metal foil; forming a wiring conductor on the insulating layer of each of the product forming regions; forming a groove portion configured to expose the upper surface of the metal foil by removing the insulating layer formed in a region, other than each of the product forming regions; and forming a frame portion including a plated conductor layer in close contact with a side surface of the insulating layer of each of the product forming regions by depositing the plated conductor layer in the groove portion.

According to the multi-piece wiring board according to the second embodiment of the present invention, the multi-piece wiring board has the configuration described above, and therefore, when a semiconductor element is mounted on each of the wiring boards, and a sealing resin layer covering the semiconductor element is formed over substantially the entire surface of the upper surface, subsequently the bottom plate is removed by peeling, and the metal foil and the frame portion are removed by etching, then the boundary of each of the wiring boards is formed by the step where the frame portion is removed, and the wiring board itself is not present. Therefore, when the cutting and dividing are performed by dicing along the boundary of each of the wiring boards, it is sufficient to cut only the sealing resin layer, the cracking or chipping does not occur in the wiring board.

Furthermore, according to the multi-piece wiring board according to the second embodiment of the present invention, the shape of the opening of the frame portion is, for example, a quadrangular shape with rounded corners or a shape other than a quadrangle. Thus, a semiconductor element is mounted on each of the wiring boards, and a sealing resin layer configured to cover the semiconductor element over substantially the entire surface of the upper surface is formed, subsequently the bottom plate is removed by peeling, and the metal foil and the frame portion are removed by etching, then only the sealing resin layer is cut by dicing along the boundary of each of the wiring boards, whereby, although the sealing resin has a quadrangular shape with sharp corners, the wiring board itself can have a quadrangular shape with rounded corners or a shape other than a quadrangle.

In addition, according to the method for producing a multi-piece wiring board according to the second embodiment of the present invention, it is possible to provide a multi-piece wiring board where the cracking or chipping is less likely to occur in the wiring board during the dicing by the above processes. Furthermore, in case of removing the insulating layer around the product forming region, when the insulating layer is removed so that the shape of the wiring board formed on the metal foil includes a quadrangle with rounded corners or a shape other than a quadrangle, after the dividing by dicing, it is possible to provide a multi-piece wiring board capable of forming a wiring board having a quadrangle with rounded corners or another shape other than a quadrangle,

### BRIEF DESCRIPTION OF THE DRAWINGS

FIGS. 1A and 1B are a schematic cross-sectional view and an exploded perspective view seen from the upper surface side showing a multi-piece wiring board according to a first embodiment;

FIGS. 2A and 2B are a schematic cross-sectional view and a perspective view seen from the upper surface side showing a state where semiconductor elements are mounted on the multi-piece wiring board shown in FIGS. 1A and 1B;

FIGS. 3A and 3B are a schematic cross-sectional view and a perspective view seen from the upper surface side showing a state where a sealing resin layer is formed on the multi-piece wiring board on which semiconductor elements are mounted shown in FIGS. 2A and 2E;

FIGS. 4A and 4B are a schematic cross-sectional view and a perspective view seen from the upper surface side showing a state where solder bumps are formed on the multi-piece wiring board on which the sealing resin layer is formed shown in PIGS. 3A and 3B;

FIGS. 5A and 5B are a schematic cross-sectional view and a perspective view seen from the lower surface side showing a state where a supporting board in the multi-piece wiring board shown in FIGS. 4A and 4B is removed, by etching;

FIGS. 6A and 6B are a schematic cross-sectional view and a perspective view seen from the lower surface side showing a state where the multi-piece wiring board from which the supporting board is removed shown in FIGS. 5A and 5B is divided by dicing;

FIGS. 7A and 7B are a schematic cross-sectional view and a perspective view seen from, the upper surface side showing a state where the multi-piece wiring board with the supporting board shown in FIGS. 4A and 4B is divided by dicing together with the sealing resin layer;

FIGS. 8A and 8B are a schematic cross-sectional view and a perspective view seen from the upper surface side for illustrating a method for producing the multi-piece wiring board according to the first embodiment;

FIGS. 9A and 9B are a schematic cross-sectional view and a perspective view seen from the upper surface side for illustrating a method for producing the multi-piece wiring board according to the first embodiment;

FIGS. 10A and 10B are a schematic cross-sectional view and a perspective view seen from the upper surface side for illustrating a method for producing the multi-piece wiring board according to the first embodiment;

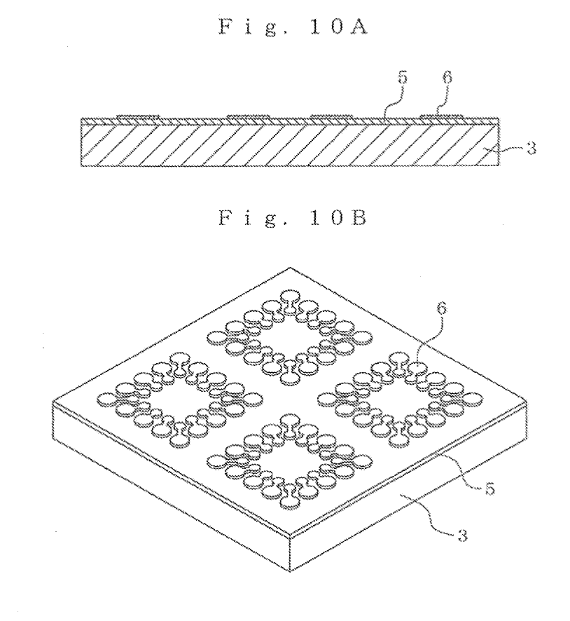

FIGS. 11A and 11B are a schematic cross-sectional view and a perspective view seen from the upper surface side for illustrating a method for producing the multi-piece wiring board according to the first embodiment;

FIGS. 12A and 12B are a schematic cross-sectional view and a perspective view seen from the upper surface side for illustrating a method for producing the multi-piece wiring board according to the first embodiment;

FIGS. 13A and 13B are a schematic cross-sectional view and a perspective view seen from the upper surface side for illustrating a method for producing the multi-piece wiring board according to the first embodiment;

FIGS. 14A and 14B are a schematic cross-sectional view and an exploded perspective view seen from the upper surface side showing a multi-piece wiring board according to a second embodiment;

FIGS. 15A and 15B are a schematic cross-sectional view and a perspective view seen from the upper surface side showing a state where semiconductor elements are mounted, on the multi-piece wiring board shown in FIGS. 14A and 14B;

FIGS. 16A and 16B are a schematic cross-sectional view and a perspective view seen from the upper surface side showing a state where a sealing resin layer is formed on the multi-piece wiring board on which semiconductor elements are mounted shown in FIGS. 15A and 15B;

FIGS. 17A and 17B are a schematic cross-sectional view and a perspective view seen from the upper surface side showing a state where solder bumps are formed on the multi-piece wiring board on which the sealing resin layer is formed shown in FIGS. 16A and 16B;

FIGS. 18A and 18B are a schematic cross-sectional view and a perspective view seen from the upper surface side showing a state where the outer peripheral portion, of the multi-piece wiring board shown in FIGS. 17A and 17B is cut;

FIGS. 19A and 19B are a schematic cross-sectional view and a perspective view seen from the upper surface side showing a state where the bottom plate of the multi-piece wiring board whose outer peripheral portion is cut shown in FIGS. 18A and 18B is peeled off and removed;

FIGS. 20A and 20B are a schematic cross-sectional view and a perspective view seen from the lower surface side showing a state where the metal foil and the frame portion are removed by etching from the multi-piece wiring board shown in FIGS. 19A and 19B;

FIGS. 21A and 21B are a schematic cross-sectional view and a perspective view seen from the lower surface side showing a state where the multi-piece wiring board from which the supporting board is removed shown in FIGS. 20A and 20B is divided by dicing;

FIGS. 22A and 22B are a schematic cross-sectional view and a perspective view seen, from the upper surface side for illustrating a method for producing the multi-piece wiring board according to the second embodiment;

FIGS. 23A and 23B are a schematic cross-sectional view and a perspective view seen from the upper surface side for illustrating a method for producing the multi-piece wiring board according to the second embodiment;

FIGS. 24A and 24B are a schematic cross-sectional view and a perspective view seen from the upper surface side for illustrating a method for producing the multi-piece wiring board according to the second embodiment;

FIGS. 25A and 25B are a schematic cross-sectional view and a perspective view seen from the upper surface side for illustrating a method for producing the multi-piece wiring board according to the second embodiment;

FIGS. 26A and 26B are a schematic cross-sectional view and a perspective view seen from the upper surface side for illustrating a method for producing the multi-piece wiring board according to the second embodiment;

FIGS. 27A and 27B are a schematic cross-sectional view and a perspective view seen from the upper surface side for illustrating a method for producing the multi-piece wiring board according to the second embodiment; and

FIGS. 28A and 28B are a schematic cross-sectional view and a perspective view seen from the upper surface side for illustrating a method for producing the multi-piece wiring board according to the second embodiment.

### DETAILED DESCRIPTION

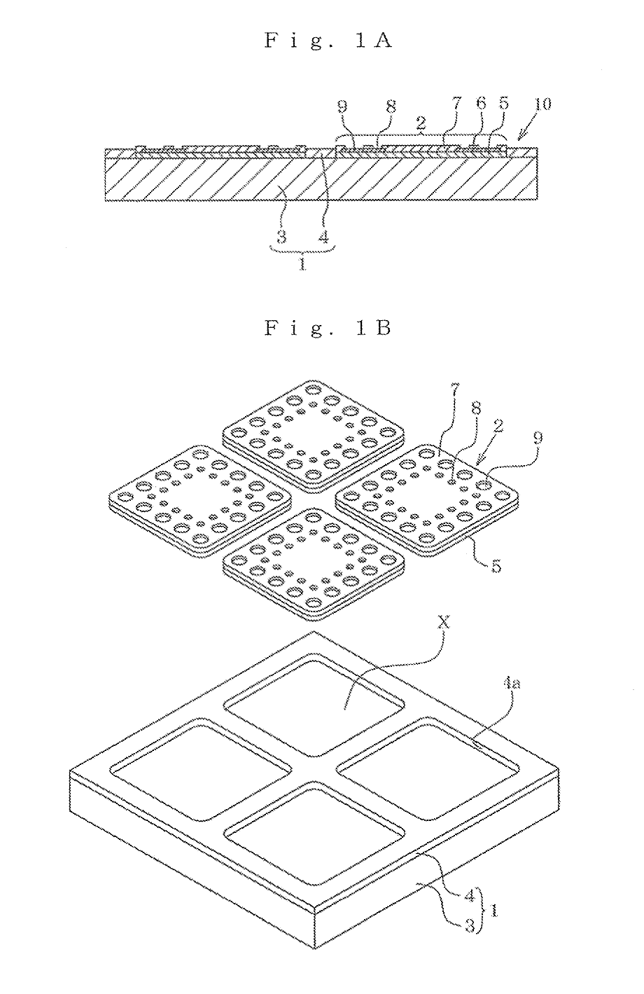

Next, the multi-piece wiring board according to the first embodiment will be described with reference to the accompanying drawings. As shown in FIGS. 1A and 1B, the multi-piece wiring board 10 according to the first embodiment includes a supporting board 1, and wiring boards 2 formed on the supporting board 1.

The supporting board 1 includes a fiat bottom plate 3, and a frame portion 4 formed on the bottom plate 3. The bottom plate 3 includes a plurality of product forming regions X on the upper surface thereof. The frame portion 4 has openings 4a that divide the respective product forming regions X. In the multi-piece wiring board 10 according to the first embodiment, the inner periphery of the opening 4a has a quadrangular shape with rounded corners. The bottom plate 3 includes, for example, copper foil having a thickness of about 100 to 200 μm. The frame portion 4 includes, for example, an electrolytic copper plating layer having a thickness of about 20 to 40 μm. It should be noted that although a case where the multi-piece wiring board 10 has four product forming regions X is shown for simplicity in the multi-piece wiring board 10 according to the first embodiment, a larger number (usually, about 100 to 10000 pieces) of product forming regions X are arranged in practice.

The wiring board 2 is formed on the product forming region X of the supporting board 1 so as to be in close contact with the bottom plate 3 and the inner peripheral surface of the frame portion 4, and exposes the upper surface of the frame portion 4. The wiring board 2 includes an insulating layer 5 formed on the bottom plate 3 of the product forming region X, a wiring conductor 6 formed on the insulating layer 5, and a solder resist layer 7 formed on the wiring conductor 6.

The insulating layer 5 includes, for example, an electrically insulating material obtained by dispersing an inorganic insulating filler such as silica in a thermosetting resin such as an epoxy resin or a polyimide resin. The thickness of the insulating layer 5 is, for example, about 10 to 30 μm. The wiring conductor 6 includes, for example, a copper plating layer. The thickness of the wiring conductor 6 is, for example, abort 5 to 15 μm. Part of the wiring conductor 6 forms semiconductor element connection pads 8 and external connection pads 9. These semiconductor element connection pads 8 and external connection pads 9 are exposed to the outside from the openings formed in the solder resist layer 7.

The solder resist layer 7 includes, for example, a photosensitive thermosetting resin such as an acrylic-modified epoxy resin. The thickness of the solder resist layer 7 is about 5 to 15 μm on the wiring conductor 6.

Here, the method for producing a semiconductor device where a semiconductor element is mounted on each of the wiring boards 2 and sealed with a resin will be described by using the multi-piece wiring board 10 according to the first embodiment.

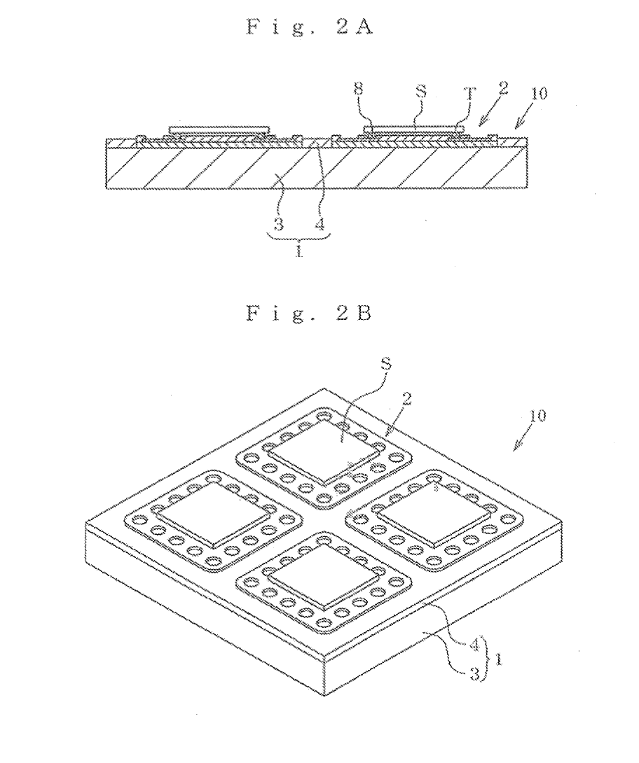

As shown in FIGS. 2A and 2B, a semiconductor element S is mounted on each of the wiring boards 2 of the multi-piece wiring board 10. The mounting of the semiconductor element S is performed by the electrode terminals T of the semiconductor element S being flip-chip connected via solder to the semiconductor element connection pads 8 of the wiring board 2.

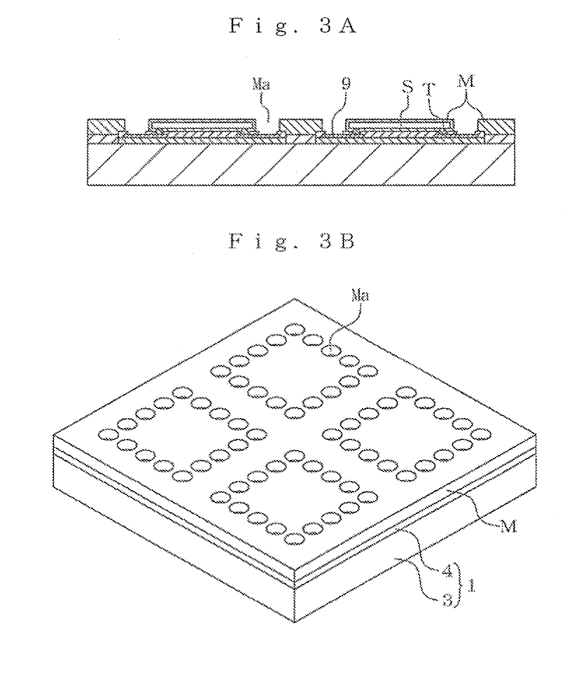

Next, as shown in FIGS. 3A and 3B, the upper surface of the multi-piece wiring board 10 on which the semiconductor elements S are mounted is covered with a sealing resin layer M. The sealing resin layer M covers the semiconductor element S, and has openings Ma configured to expose the external connection pads 9, The sealing resin layer H is formed, for example, by a transfer molding method.

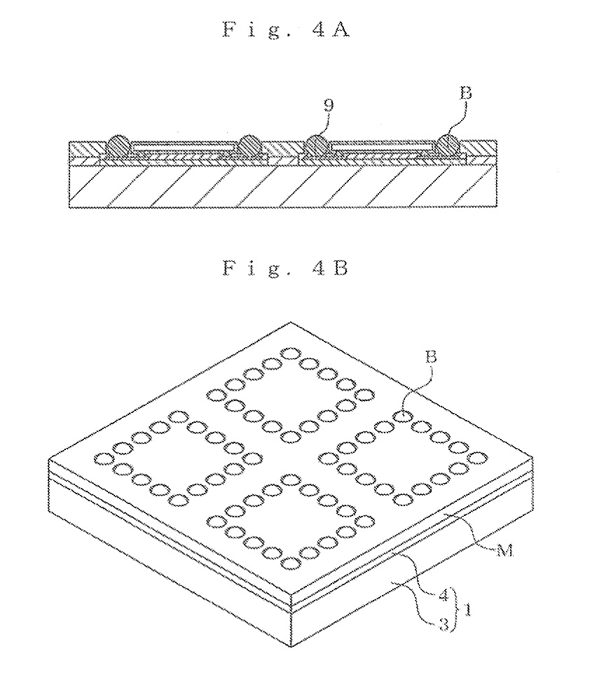

Next, as shown in FIGS. 4A and 4B, a solder bump B is formed on the external connection pad 9 exposed, in the opening Ma. The solder bump B is formed, for example, after the flux is applied in the opening Ma, by a solder bail being placed thereon and by the ref low processing being performed.

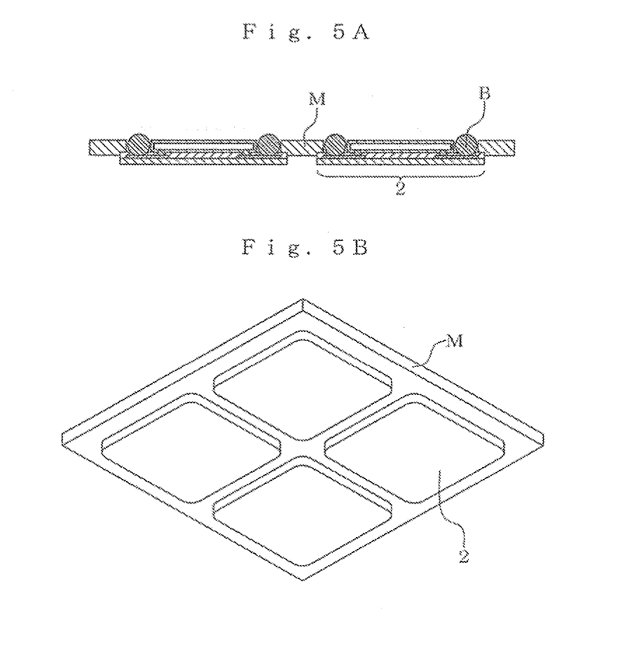

Next, as shown in FIGS. 5A and 5B, the supporting board 1 is removed by etching. The supporting board 1 includes copper, and therefore, can be easily etched, by an etching solution containing, for example, ferric chloride, copper chloride, and the like being used. In this case, the boundary of each of the wiring boards 2 is formed by the step of the trace where the frame portion 4 is removed. In the step portion, the insulating layer 5, the wiring conductor 6, and the solder resist layer 7 included in the wiring board 2 are not present, and only the sealing resin layer M is present.

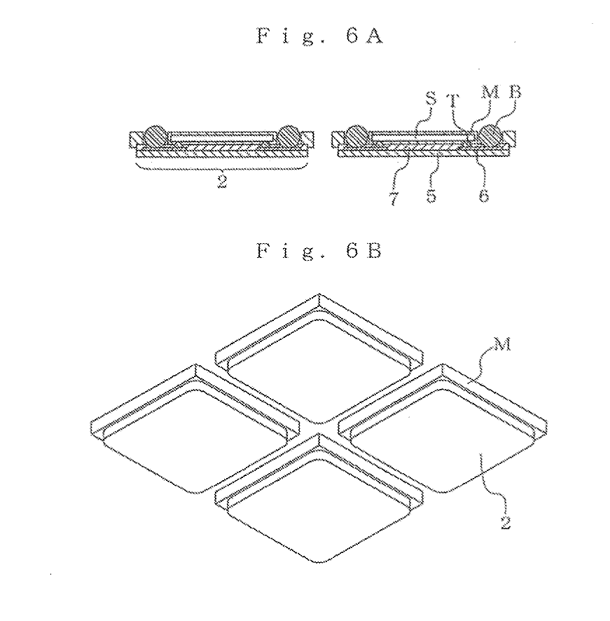

Next, as shown In FIGS. 6A and 6B, the dicing is performed along the boundary of each of the wiring boards 2, whereby the semiconductor device where the semiconductor element S mounted on the wiring board 2 is sealed by the sealing resin layer M is formed. In this case, it is sufficient to cut only the sealing resin layer M positioned, at the boundary of the wiring board 2, and therefore, the cracking or chipping does not occur in the wiring board 2 by the dicing stress.

According to the multi-piece wiring board 10, the Inner periphery of the opening 4a of the supporting board 1 has a quadrangular shape with rounded corners, and the wiring board 2. is formed on the product forming region X of the supporting board 1 so as to be in close contact with the bottom plate 3 and the inner peripheral surface of the opening 4a. As described above, the semiconductor element S is mounted, on each, of the wiring, boards 2, and the sealing resin layer M covering the semiconductor element S is formed on the upper surface of the multi-piece wiring board 10. Next, after the supporting board 1 is removed by etching, only the sealing resin layer M is cut along the boundary of each of the wiring boards 2 by dicing. Therefore, in the resultant semiconductor device, although the sealing resin layer M has a quadrangular shape with sharp corners, the wiring board 2 itself can have a quadrangular shape with rounded corners. Furthermore, the shape of the opening 4a of the frame portion 4 is a shape other than quadrangle, and the wiring board 2 is formed so as to be in close contact with the inner peripheral surface of the opening 4a, whereby a wiring board 2 of the shape other than quadrangle can be obtained.

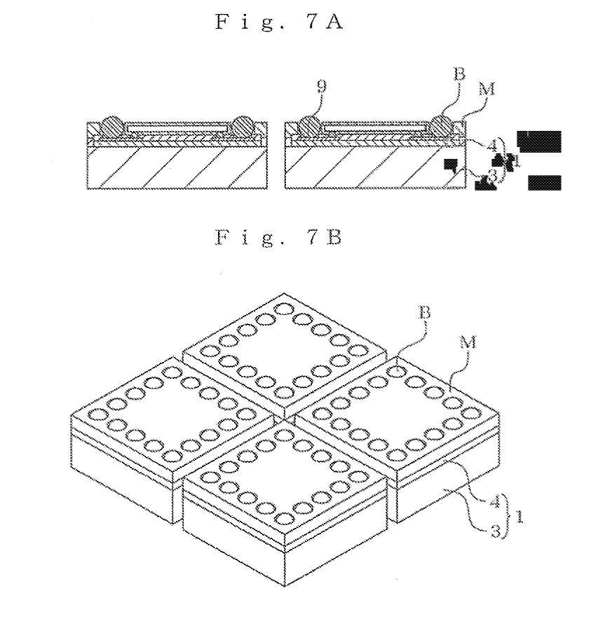

In the above-described method, after the supporting board 1 of the multi-piece wiring board 10 is removed by etching, the dicing is performed. However, as shown in FIGS. 7A and 7B, after the dicing is performed with the supporting board 1 of the multi-piece wiring board 10 attached, the supporting board 1 may be removed by etching from the divided wiring board 2.

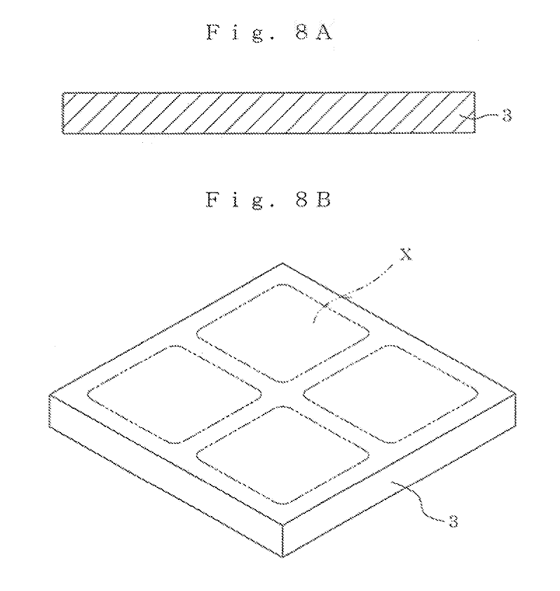

Next, a method for producing the multi-piece wiring board 10 according to the first embodiment will be described. As shown, in FIGS. 8A and 8B, a bottom plate 3 is prepared. The bottom plate 3 includes a plurality of product forming regions X on the upper surface thereof. The bottom plate 3 includes, as described above, copper foil having a thickness of about 100 to 200 μm.

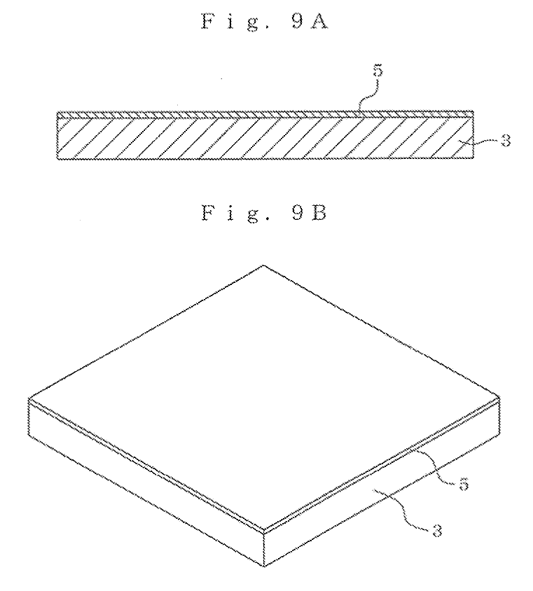

Next, as shown in FIGS. 9A and 9B, an insulating layer 5 is formed on the entire upper surface of the bottom plate 3. The insulating layer 5 includes, as described above, an electrically insulating material obtained by dispersing an inorganic insulating filler such as silica in a thermosetting resin such as an epoxy resin or a polyimide resin, and has a thickness of about 10 to 30 μm. The insulating layer 5 is, for example, formed by an uncured film of electrical insulating material being thermally cured after adhered by heat press on the upper surface of the bottom plate 3.

Next, as shown in FIGS, 10A and 10B, wiring conductors 6 are formed on the upper surface of the insulating layer 5 on each of the product forming regions X. The wiring conductor 6 includes a copper plating layer having a thickness of about 5 to 15 μm, and is formed by a well-known semi-additive method.

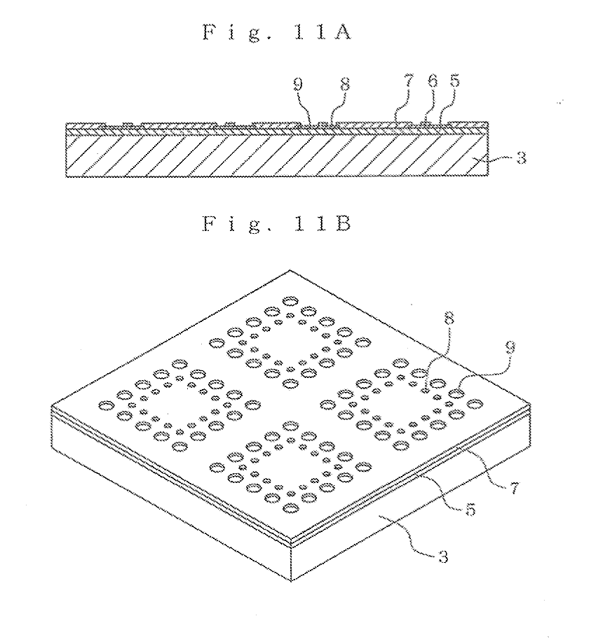

Next, as shown in FIGS. 11A and 11B, a solder resist layer 7 having openings is formed on the upper surface of the insulating layer 5 on which the wiring conductors 6 are formed. The opening is formed

so as to expose part of the wiring conductors 6 as semiconductor element connection pads 8 and external connection pads 9. The solder resist layer 7 includes a photosensitive thermosetting resin such as an acrylic-modified epoxy resin, and has a thickness of about 5 to 15 μm. The solder resist layer 7 is formed by applying a photosensitive thermosetting resin paste on the upper surface of the insulating layer 5. The opening is formed by exposing and developing a photosensitive, thermosetting resin paste by a well-known photolithography technique.

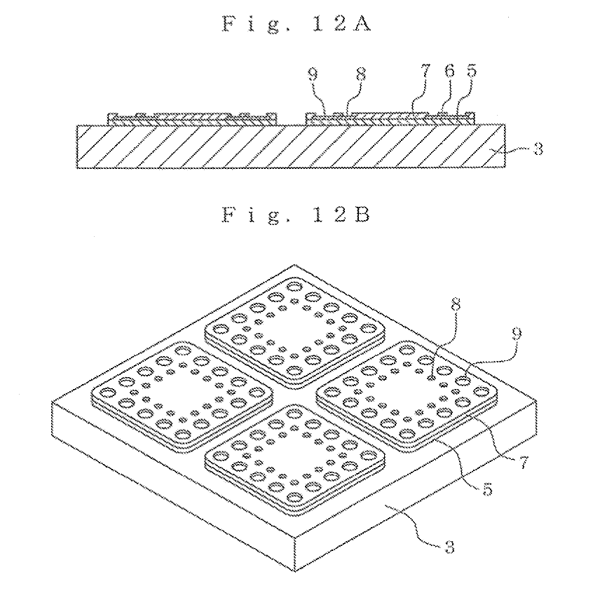

Next, as shown in FIGS. 12A and 12B, the solder resist layer 7 and the insulating layer 5 around each of the product forming regions X are selectively removed, whereby the upper surface of the bottom plate 3 around each of the product forming regions X is exposed. For the removal of the solder resist layer 7 and the insulating layer 5, for example, the sandblasting method and the laser scribing method are employed. Thus, each of the quadrangular wiring boards 2 with rounded corners is formed on the bottom plate 3 at a predetermined adjacent interval.

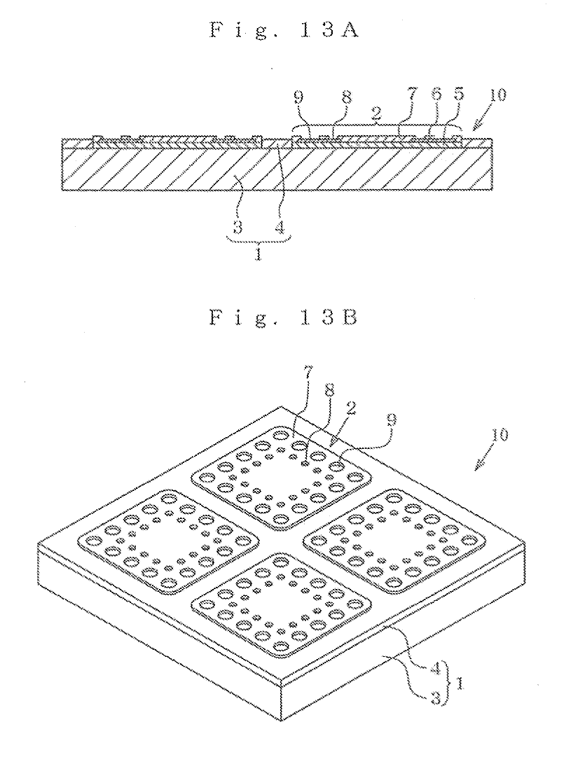

Next, as shown in FIGS. 13A and 13B, a frame portion 4 is formed around the product forming region X of the upper surface of the bottom plate 3. The frame portion 4 includes an electrolytic copper plating layer having a thickness of about 20 to 40 μm, and is formed by the electrolytic copper plating layer being deposited around the product forming region X of the upper surface of the bottom plate 3. In this case, the side surfaces of each of the wiring boards 2 come into close contact with the frame portion 4 by being wrapped in the deposited copper plating layer.

In this way, by the following processes (1) to (4), it is possible to provide a multi-piece wiring board where the cracking or chipping is less likely to occur in the wiring board during the dicing.

(1) A process of forming an insulating layer covering at least each of the product forming regions on the upper surface of the bottom plate having a plurality of product forming regions on the upper surface.

(2) A process of forming a wiring conductor on the Insulating layer of each of the product forming regions.

(3) A process of exposing the upper surface of the bottom plate by removing the insulating layer formed in the region other than each of the product forming regions.

(4) A process of forming a frame portion configured to divide the upper surface of the bottom plate into each of the product forming regions on the bottom plate by depositing a plated conductor layer on the upper surface of the exposed bottom plate.

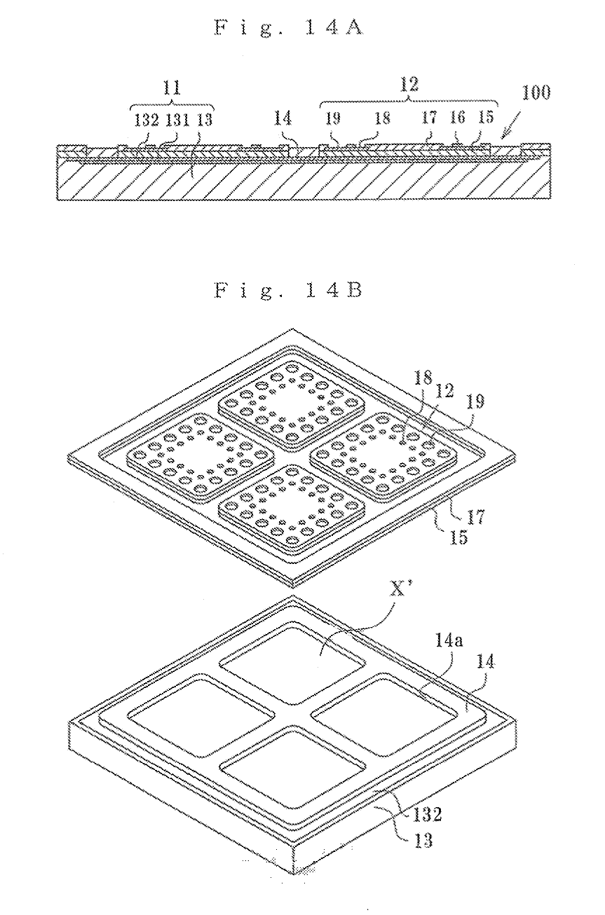

Next, the multi-piece wiring board according to the second embodiment will be described with reference to the accompanying drawings. As shown in FIGS. 14A and 14B, the multi-piece wiring board 100 according to the second embodiment includes a supporting board 11, a wiring board 12 formed on the supporting board 11, and a frame portion 14. In FIG. 14B, so as to facilitate understanding of the multi-piece wiring board 100, the supporting board 11 and the frame portion 14, and the other parts in FIG. 14A are shown separately.

The supporting board 11 includes a flat bottom plate 13, a first metal foil 131 deposited on the bottom plate 13, and a second metal foil 132 laminated on the first metal foil 131. The bottom plate 13 includes, for example, an epoxy resin board containing glass cloth. The thickness of the bottom plate 13 is about 100 to 1000 μm.

The first metal foil 131 preferably includes copper foil having a thickness of about 3 to 18 μm. The first metal foil 131 has a smaller size than the bottom, plate 13. The outer periphery of the first metal foil 131 is disposed about 2 to 20 mm further inward than the outer periphery of the bottom plate 13. The entire lower surface of the first metal foil 131 is fixed on the upper surface of the bottom plate 13.

The second metal foil 132 includes etchable metal foil, preferably, copper foil having a thickness of about 3 to 18 μm. The second metal foil 132 has a size larger than the first metal foil 131, and smaller than the bottom plate 13. The outer periphery of the second metal foil 132 is disposed about 1 to 10 mm outward further than the outer periphery of the first metal foil 131, and about 1 to 10 mm inward further than the outer periphery of the bottoms plate 13. In the second metal foil 132, the lower surface of the side outer than the outer periphery of the first metal foil 131 is fixed on the upper surface of the bottom plate 13.

The first metal foil 131 and the second metal foil 132 are in close contact with each other in a peelable state. Thus, although the second metal foil 132 is fixed on the bottom plate 13 in the outer peripheral portion protruding from the first metal foil 131, the second metal foil 132 is peelable between the first metal foil 131 and the second, metal foil 132, from the bottom plate 13 in the central portion in close contact with the first metal foil 131.

The second metal foil 132 includes a plurality of product forming regions X′ on the upper surface thereof. The product forming regions X′ are disposed mutually at a predetermined interval in the laminated central portion peelable from the bottom plate 13 in the second metal foil 132. The product forming region X′ is a region where the wiring board 12 is formed on the upper surface thereof.

The frame portion 14 is formed on the second metal foil 132. The frame portion 14 has openings 14a that divide the respective product forming regions X′. In the multi-piece wiring board 100 according to the second embodiment, the inner periphery of the opening 14a has a quadrangular shape with rounded corners. The frame portion 14 includes an etchable metal plating layer, preferably, an electrolytic copper plating layer having a thickness of about 20 to 40 μm. It should be noted that although a case where the multi-piece wiring board 100 has four product forming regions X′ is shown for simplicity in the multi-piece wiring board 100 according to the second embodiment, a larger number (usually, about 100 to 10000 pieces) of product forming regions X′ are arranged in practice.

The wiring board 12 is formed on each of the product forming regions X′ of the second metal foil 132 so as to be in close contact with the inner peripheral surface of the opening 14a of the frame portion 14. Therefore, the outer peripheral shape of the wiring board 12 matches the inner peripheral shape of the opening 14a. The wiring board 12 includes an insulating layer 15 deposited on the product farming region X′, a wiring conductor 16 deposited on the insulating layer 15, and a solder resist layer 17 formed on the wiring conductor 16.

The insulating layer 15 includes, for example, an electrically insulating material obtained by dispersing an inorganic insulating filler such as silica In a thermosetting resin such as an epoxy resin or a polyimide resin. The thickness of the insulating layer 15 is, for example, about 10 to 30 μm. The wiring conductor 16 includes, for example, a copper plating layer. The thickness of the wiring conductor 16 is, for example, about 5 to 15 μm. Part of the wiring conductor 16 forms semiconductor element connection pads 18 and external connection pads 19. These semiconductor element connection pads 18 and external connection pads 19 are exposed to the outside from the openings formed in the solder resist layer 17. The solder resist layer 17 includes, for example, a photosensitive thermosetting resin such as an acrylic-modified epoxy resin. The thickness of the solder resist layer 17 is about 5 to 15 μm on the wiring conductor 16.

Here, the method for producing a semiconductor device where a semiconductor element is mounted on each of the wiring boards 12 and sealed with a resin will be described by using the multi-piece wiring board 100 according to the second embodiment.

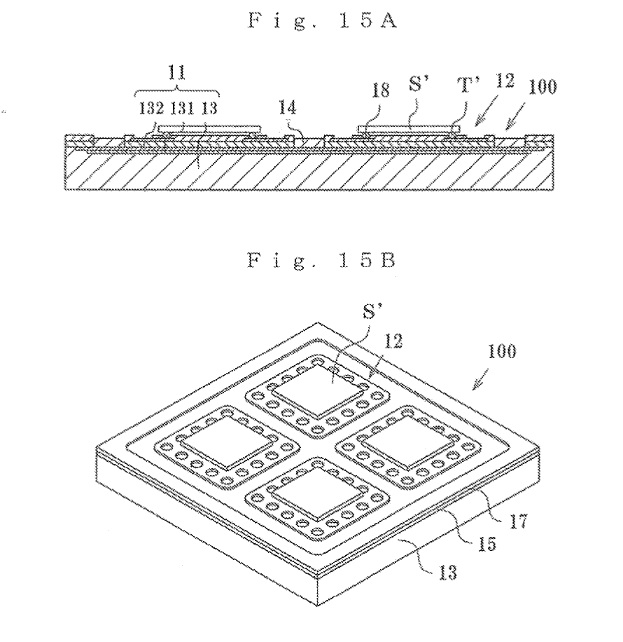

As shown in FIGS. 15A and 15B, a semiconductor element S′ is mounted on each of the wiring boards 12 of the multi-piece wiring board 100. The mounting of the semiconductor element S′ is performed by the electrode terminals T′ of the semiconductor element S′ being flip-chip connected via solder to the semiconductor element connection pads 18 of the wiring board 12.

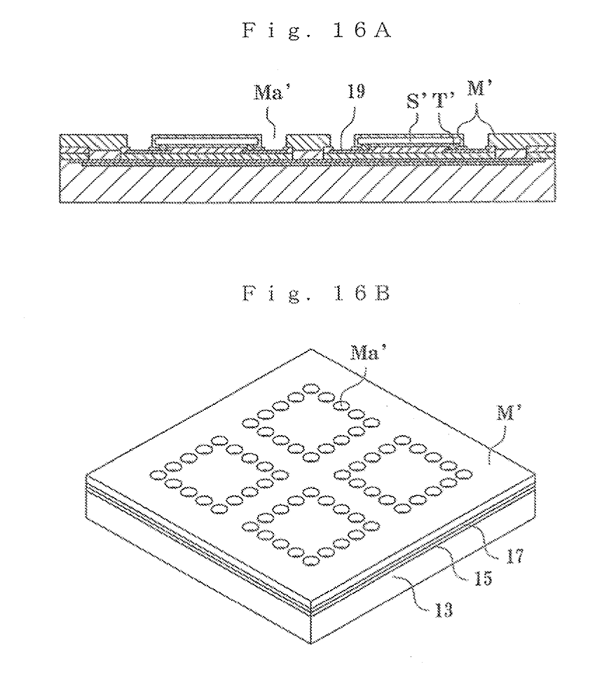

Next, as shown in FIGS. 16A and 16B, the upper surface of the multi-piece wiring board 100 on which the semiconductor elements S are mounted is covered with a sealing resin layer M′. The sealing resin layer M′ covers the semiconductor element S′, and has openings Ma′ configured to expose the external connection pads 19. The sealing resin layer M′ is formed, for example, by a transfer molding method.

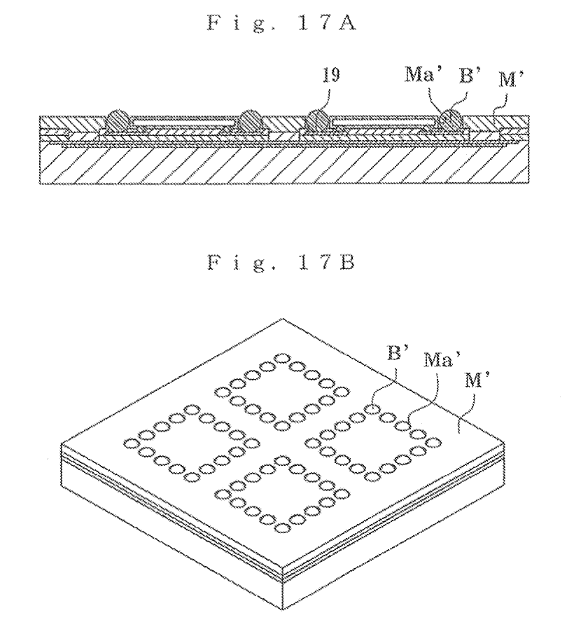

Next, as shown in FIGS. 17A and 17B, a solder bump B′ is formed on the external connection pad 19 exposed in the opening Ma′. The solder bump B′ is formed, for example, after the flux is applied in the opening Ma′, by a solder bail being placed thereon and by the reflow processing being performed.

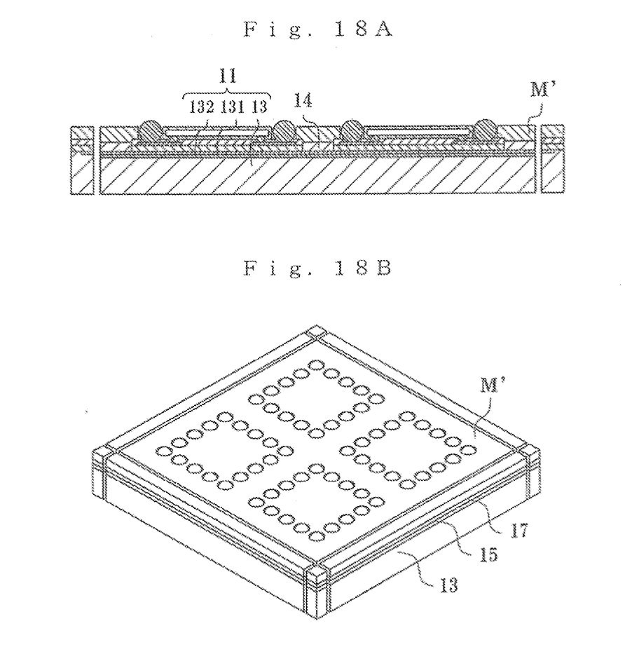

Next, as shown in FIGS. 18A and 18B, the outer peripheral portion of the laminated body including the supporting board 11, the insulating layer 15, the solder resist layer 17, and the sealing resin layer M′ is cut to foe removed. In this case, the portion where the first metal foil 131 and the second metal foil 132 are in close contact with each other in a peelable state is cut as a boundary. As a result, the peeling between the second metal foil 132 and the first metal foil 131 fixed on the bottom plate 13 becomes easy.

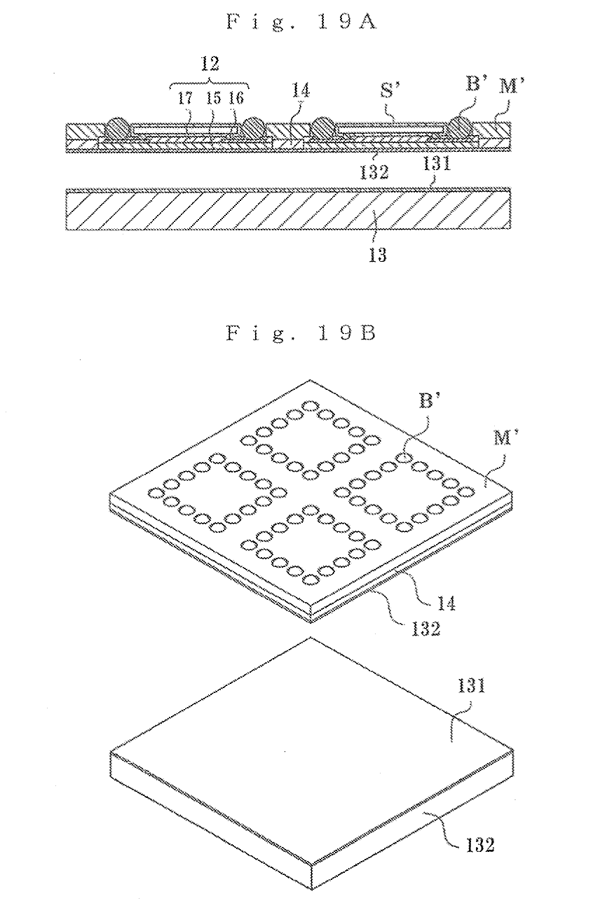

Next, as shown in FIGS. 19A and 19B, the peeling is performed between the first metal foil 131 and the second metal foil 132. Thus, the lower surface of the wiring board 12 becomes a state where only the second metal foil 132 having a thickness as thin as 3 to 18 μm is deposited.

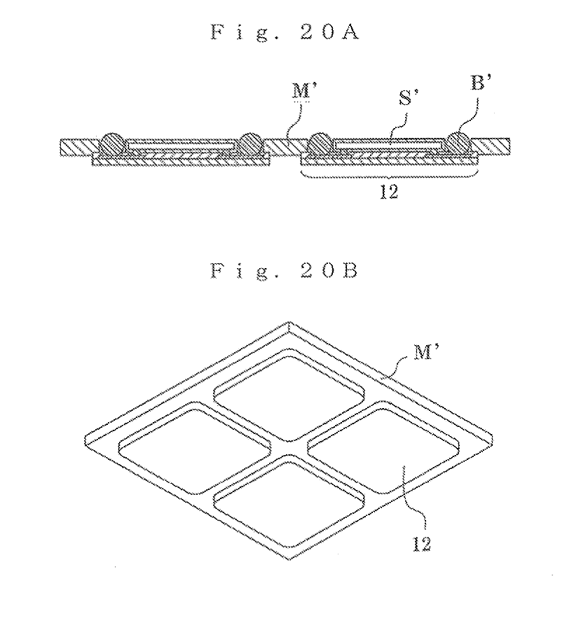

Next, as shown in FIGS. 20A and 20B, the second metal foil 132 on the lower surface of the wiring board 12 and the frame portion 14 in close contact with the side surface of the wiring board 12 are removed by etching. The second metal foil 132 and the frame portion 14 include copper, and therefore, can be easily etched by an etching solution containing, for example, ferric chloride, copper chloride, and the like being used. In this case, the boundary of each of the wiring boards 12 is formed toy the step of the trace where the frame portion 14 is removed. In the step portion, the insulating layer 15, the wiring conductor 16, and the solder resist layer 1 included in the wiring board 12 are not present, and only the sealing resin layer M′ is present.

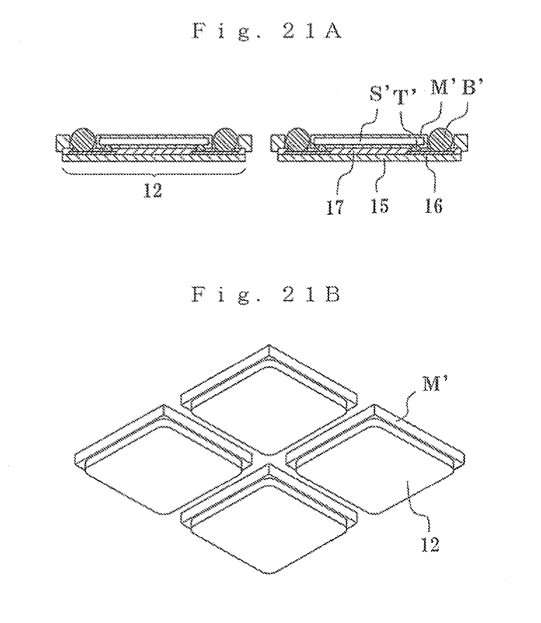

Next, as shown in FIGS. 21A and 21B, the dicing is performed along the boundary of each of the wiring boards 12, whereby the semiconductor device where the semiconductor element S′ mounted on the wiring board 12 is sealed by the sealing resin layer M′ is formed. In this case, it is sufficient to cut only the sealing resin layer M′ positioned at the boundary of the wiring board 12, and therefore, the cracking or chipping does not occur in the wiring board 12 by the dicing stress. In the above-described method, after the peeling is performed between the first metal foil 131 and the second metal foil 132, and the second metal foil 132 and the frame portion 14 are removed, the dicing is performed along the boundary of each of the wiring boards 12, However, after the dicing is performed along the boundary of each of the wiring boards 12, the peeling may be performed between the first metal foil 131 and the second metal foil 132, and the second metal foil 132 and the frame portion 14 may be removed from the divided wiring board 12.

According to the multi-piece wiring board 100, the inner periphery of the opening 14a of the frame portion 14 has a quadrangular shape with rounded corners, and the wiring board 12 is formed on the product forming region X′ so as to be in close contact with the inner peripheral surface of the opening 14a. As described above, after the semiconductor element S′ is mounted on each of the wiring boards 12, and the sealing resin layer M′ covering the semiconductor element S′ on the upper surface of the multi-piece wiring board 100 is formed, the outer peripheral portion is cut to be removed. Next, after the second metal foil 132 and the frame portion 14 are removed by etching, only the sealing resin layer M′ is cut by dicing along the boundary of each of the wiring boards 12. Therefore, in the semiconductor device to be obtained, although the sealing resin layer M′ has a quadrangular shape with sharp corners, the wiring board 12 itself can have a quadrangular shape with rounded corners. Furthermore, the shape of the opening 14a of the frame portion 14 is a shape other than quadrangle, and the wiring board 12 is formed so as to be in close contact with the inner peripheral surface of the opening 14a, whereby a wiring board 12 of the shape other than a quadrangle can be obtained.

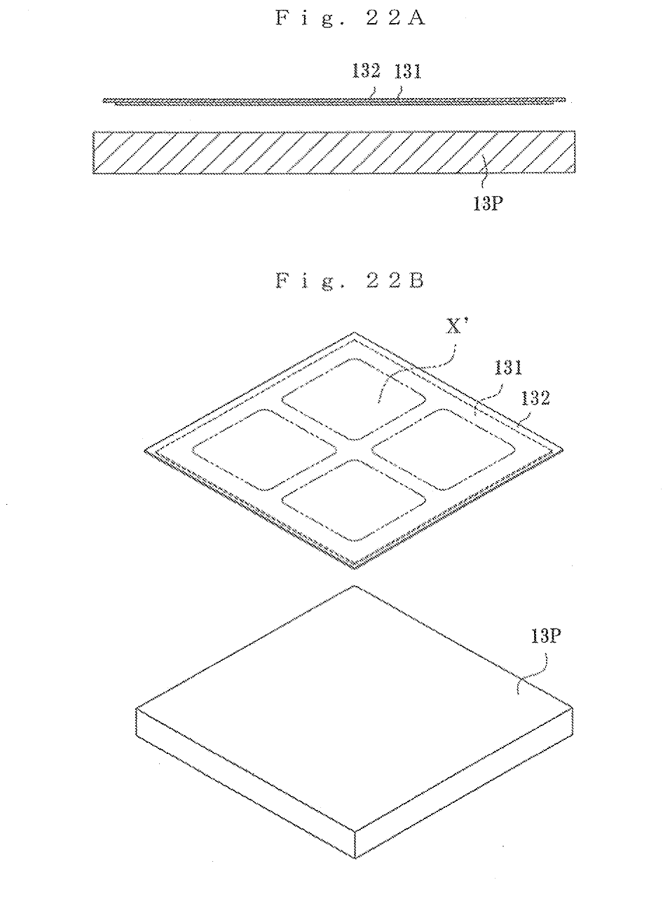

Next, a method for producing the multi-piece wiring board 100 according to the second embodiment will be described. As shown in FIGS. 22A and 228, the prepreg 13P for the bottom plate 13, the first metal foil 131, and the second metal foil 132 are prepared. The prepreg 13P can be obtained, for example, by a liquid resin in an uncured state of a thermosetting resin such as an epoxy resin being dried after impregnated and applied in a sheet-like base material including glass cloth. As described above, the first metal foil 131 and the second metal foil 132 include, for example, copper foil, and are laminated in a peelable state from each other. The second metal foil 132 includes a plurality of product forming regions X′ on the upper surface thereof.

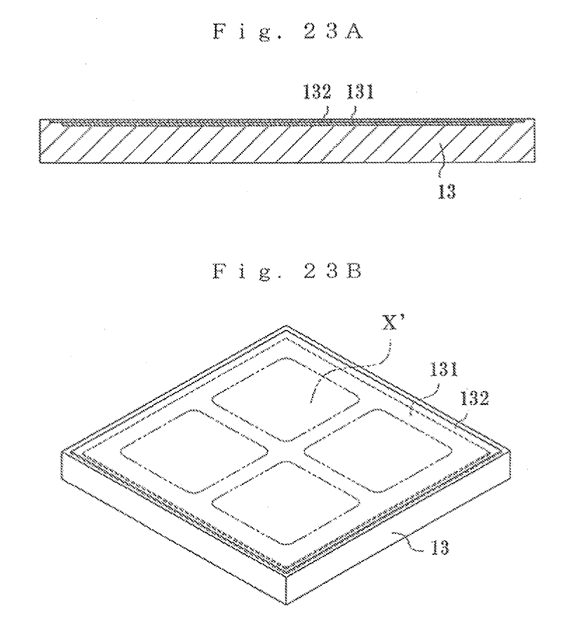

Next, as shown in FIGS. 23A and 23B, a laminated body of the first metal foil 131 and the second metal foil 132 is deposited on the upper surface of the bottom plate 13. To deposit the laminated body of the first metal foil 131 and second metal foil 132 on the upper surface of the bottom plate 13, the methods of placing the laminated body of the first metal foil 131 and the second metal foil 132 on the upper surface of the prepreg 13P, and vacuum-pressing the laminated body from above and below while heating the laminated body are employed. As a result, the entire lower surface of the first metal foil 131 is fixed on the upper surface of the bottom plate 13, and the lower surface of the second metal foil 132 protruding from the first metal foil 131 is fixed on the upper surface of the bottom plate 13.

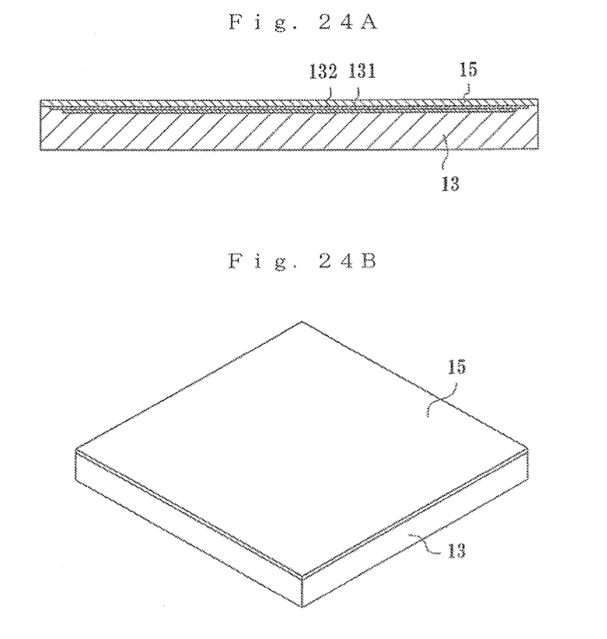

Next, as shown in FIGS. 24A and 24B, an insulating layer 15 is formed so as to cover the entire surface of the upper surface of the second metal foil 132. The insulating layer 15 includes, as described above, an electrically insulating material obtained by dispersing an inorganic insulating filler such as silica In a thermosetting resin such as an epoxy resin or a polyimide resin, and has a thickness of about 10 to 30 μm. The insulating layer 15 is, for example, formed by an uncured film of electrical insulating material being thermally cured after adhered by heat press on the second metal foil 132.

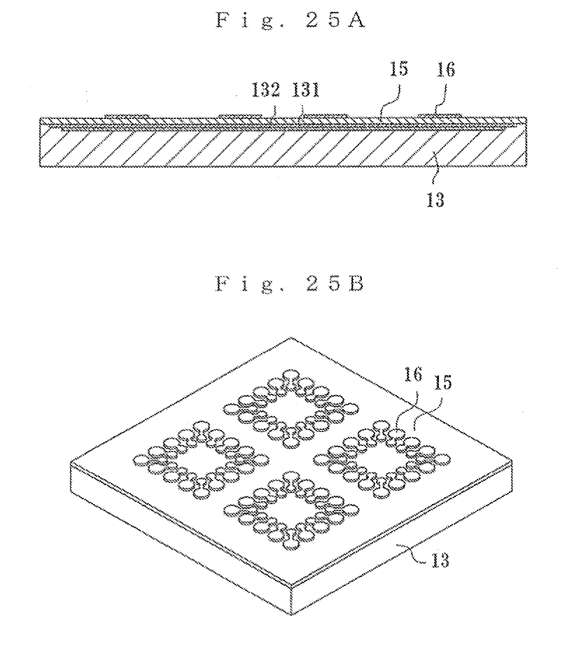

Next, as shown in FIGS. 25A and 25B, wiring conductors 16 are formed on the upper surface of the insulating layer 15 on each of the product forming regions X′. The wiring conductor 16 includes a copper plating layer having a thickness of about 5 to 15 μm, and is formed by a well-known semi-additive method.

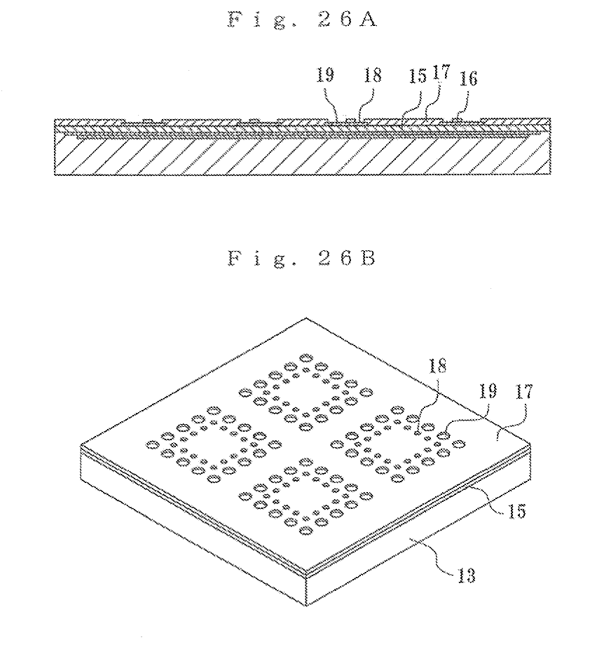

Next, as shown in FIGS. 26A and 26B, a solder resist layer 17 having openings is formed on the upper surface of the insulating layer 15 on which the wiring conductors 16 are formed. The opening is formed so as to expose part of the wiring conductors 16 as semiconductor element connection pads 18 and external connection pads 19. The solder resist layer 17 includes a photosensitive thermosetting resin such as an acrylic-modified epoxy resin, and has a thickness of about 5 to 15 μm. The solder resist layer 17 is formed by applying a photosensitive thermosetting resin paste on the upper surface of the insulating layer 15. The opening is formed by exposing and developing a photosensitive thermosetting resin paste by a well-known photolithography technique.

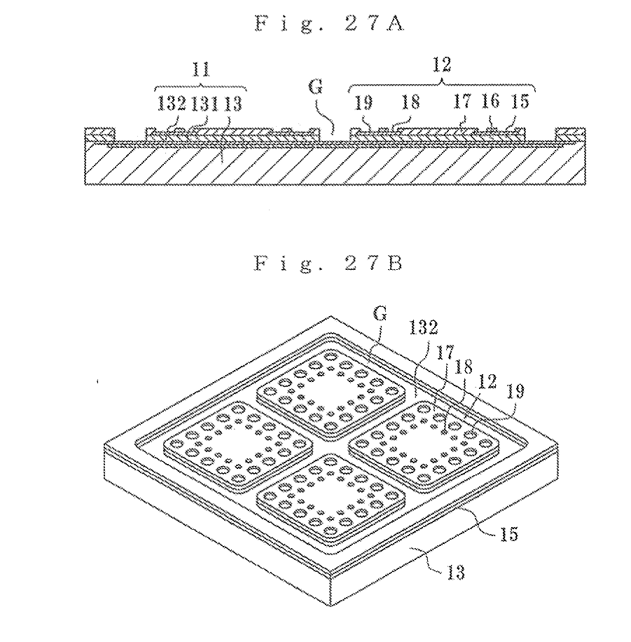

Next, as shown in FIGS. 27A and 27B, the solder resist layer 17 and the insulating layer 15 around each of the product forming regions X′ are selectively removed, and a groove portion G exposing the upper surface of the second metal foil, 132 around each of the product forming regions X′ in a frame shape is formed. For the removal of the solder resist layer 17 and the insulating layer 15, for example, the sandblasting method and the laser scribing method are employed. Thus, each of the quadrangular wiring boards 12 with rounded corners is formed on the second metal foil 132 at a predetermined adjacent interval.

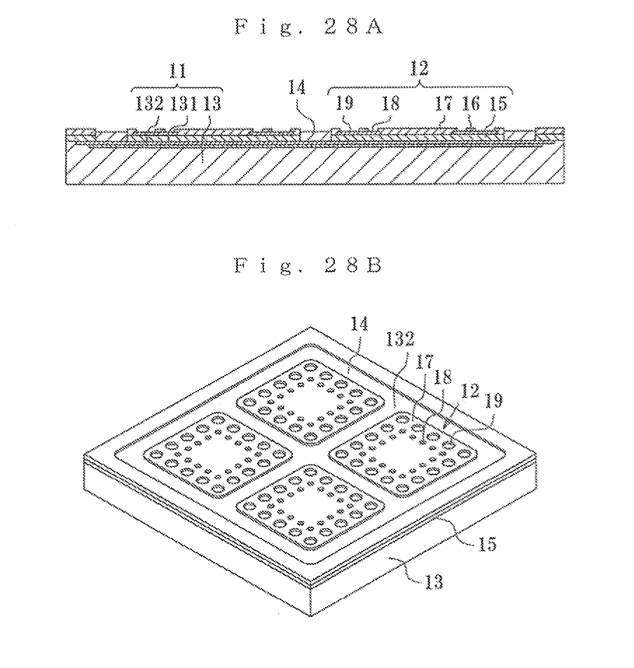

Next, as shown in FIGS. 23A and 28B, a frame portion 14 is formed on the upper surface of the second metal foil 132 exposed in the groove portion G around the product forming regions X′. The frame portion 14 is formed by depositing an electrolytic copper plating layer on the exposed surface of the second metal foil 132. In this case, the frame portion 14 is in close contact with the side surface of each of the wiring boards 12.

In this way, by the following processes (1)′ to (5)′, it is possible to provide a multi-piece wiring board where the cracking or chipping is less likely to occur in the wiring board during the dicing.

(1) A process of laminating metal foil including a plurality of product forming regions in the central portion of the upper surface of the metal foil on the upper surface of the bottom plate in a state where at least the central portion is peelable from the bottom plate.

(2) A process of forming an insulating layer on the entire surface of at least the central portion on the metal foil,

(3) A process of forming a wiring conductor on the Insulating layer of each of the product forming regions.

(4) A process of forming a groove portion configured to expose the upper surface of the metal foil by removing the insulating layer formed in the region other than each of the product forming regions.

(5) A process of forming a frame portion including a plated conductor layer in close contact with the side surface of the insulating layer of each of the product forming regions by depositing the plated conductor layer in the groove.

The present invention is not intended to be limited to the embodiments described above, and various modifications are possible as long as they do not depart from the gist of the present invention. For example, although the wiring conductor is formed by a semi-additive method in the embodiments described above, the wiring conductor may be formed by a well-known subtractive method. In this case, copper foil can be also used as the wiring conductor. In addition, although the wiring board is formed by the insulating layer and the wiring conductor each, of which has one layer in the embodiments described above, the wiring board may be formed by a multilayer structure where a plurality of insulating layers and wiring conductors are laminated.

Furthermore, in case that the solder resist, layer and the insulating layer around each of the product forming regions are selectively removed, and the upper surface of the bottom plate around each of the product forming regions (first embodiment) or the upper surface of the second metal foil (second embodiment) are exposed, when the solder resist layer and the insulating layer are removed so that the shape of the wiring board to be formed on each of the product forming regions becomes a quadrangular shape with rounded corners or a shape other than a quadrangle (for example, a polygonal shape such as a trianglar shape, a pentagonal shape, and a hexagonal-shape, a circle), it is possible to provide a multi-piece wiring board capable of forming a wiring board having a quadrangular shape with rounded corners or a shape other than a quadrangle after the dividing by dicing.

What is claimed is:

1. A multi-piece wiring board comprising:
a supporting board including a frame portion formed on an upper surface of a bottom plate, the frame portion configured to divide the upper surface of the bottom plate into a plurality of product forming regions; and
a wiring board formed on the upper surface of the bottom plate in each of the product forming regions, the wiring board including an insulating layer formed so as to expose an upper surface of the frame portion, and
a wiring conductor formed on the insulating layer.

2. The multi-piece wiring board according to claim 1, wherein the product forming regions include openings containing a quadrangular shape with rounded corners or a shape different from a quadrangle, the openings formed in the frame portion.

3. A method for producing a multi-piece wiring board, the method comprising the steps of:
forming an insulating layer covering at least each of product forming regions on an upper surface of a bottom plate having a plurality of the product forming regions on the upper surface;
forming a wiring conductor on the insulating layer of each of the product forming regions;
exposing the upper surface of the bottom plate by removing the insulating layer formed in a region other than each of the product forming regions; and
forming a frame portion configured to divide the upper surface of the bottom plate into each of the product forming regions on the bottom plate by depositing a plated conductor layer on the upper surface of the exposed bottom plate.

4. The method for producing a multi-piece wiring board according to claim 3, wherein the product forming regions include openings containing a quadrangular shape with, rounded corners or a shape different from a quadrangle, the openings formed in the frame portion.

5. A multi-piece wiring board comprising:
a supporting board including metal foil laminated on an upper surface of a bottom plate in a state where at least a central portion of the metal foil is peelable from the bottom plate;
a frame portion including a plated metal layer, the frame portion configured to divide a central portion of an upper surface of the metal foil into a plurality of product forming regions in the central portion of the upper surface of the metal foil, the frame portion formed on the metal foil; and
a wiring board formed in each of the product forming regions, the wiring board including
an insulating layer formed so as to be in close contact with an inner wall of the product forming region, and
a wiring conductor formed on the insulating layer.

6. The multi-piece wiring board according to claim 5,
wherein other metal foil smaller than the metal foil is further fixed on the bottom plate between the bottom plate and the metal foil, and
wherein the metal foil and the other metal foil are in close contact with each other in a peelable state.

7. The multi-piece wiring board according to claim 5, wherein the product forming regions include openings containing a quadrangular shape with rounded corners or a shape different from a quadrangle, the openings formed in the frame portion.

8. A method for producing a multi-piece wiring board, the method comprising the steps of:
laminating metal foil including a plurality of product forming regions in a central portion of an upper surface of the metal foil on an upper surface of a bottom plate in a state where at least the central portion is peelable from the bottom plate;
forming an insulating layer on the entire surface of at least the central portion on the metal foil;
forming a wiring conductor on the insulating layer of each of the product forming regions;
forming a groove portion configured to expose the upper surface of the metal foil by removing the insulating layer formed in a region other than each of the product forming regions; and
forming a frame portion including a plated conductor layer in close contact with a side surface of the insulating layer of each of the product forming regions by depositing the plated conductor layer in the groove portion.

9. The method for producing a multi-piece wiring board according to claim 8,
wherein other metal foil smaller than the metal foil is further fixed on the bottom plate between the bottom plate and the metal foil, and
wherein the metal foil and the other metal foil are in close contact with each other in a peelable state.

10. The method for producing a multi-piece wiring board according to claim 8, wherein the product forming regions include openings containing a quadrangular shape with rounded corners or a shape different from a quadrangle, the openings formed in the frame portion.

11. A method for producing a semiconductor device, the method comprising the steps of:
mounting a semiconductor element on the wiring board formed in each of the product forming regions of the multi-piece wiring board according to claim 1;
covering an upper surface of the multi-piece wiring board with a sealing resin layer including an opening configured to expose an external connection pad;
forming a solder bump in the opening configured to expose the external connection pad; and
removing the supporting board of the multi-piece wiring board, and performing a cutting along a boundary of each of the wiring boards.

12. The method for producing a semiconductor device according to claim 11, further comprising the step of removing the supporting board after performing the cutting along the boundary of each of the wiring board.

13. The method for producing a semiconductor device according to claim 11, wherein the removal of the supporting board is performed by etching.

14. A method for producing a semiconductor device, the method comprising:
mounting a semiconductor element on the wiring board formed in each of the product forming regions of the multi-piece wiring board according to claim 5;
covering an upper surface of the multi-piece wiring board with a sealing resin layer including an opening configured to expose an external connection pad;
forming a solder bump in the opening configured to expose the external connection pad;
cutting an outer peripheral portion of a laminated body including the multi-piece wiring board and the sealing resin layer;
peeling between the metal foil and a bottom plate of the multi-piece wiring board;
removing the metal foil and a frame portion of the multi-piece wiring board; and
performing a cutting along a boundary of each of the wiring boards.

15. The method for producing a semiconductor device according to claim 14, wherein after a cutting along the boundary of each of the wiring boards is performed, a peeling between the metal foil and the bottom plate of the multi-piece wiring board is performed, and the metal foil and the frame portion are removed.

16. The method for producing a semiconductor device according to claim 14, wherein the removal of the metal foil and the frame portion are performed by etching.
